(19) United States
(12) Patent Application Publication
(10) Pub. No.: US 2012/0315741 A1
(43) Pub. Date: Dec. 13, 2012

(54) ENHANCED MAGNESIUM INCORPORATION INTO GALLIUM NITRIDE FILMS THROUGH HIGH PRESSURE OR ALD-TYPE PROCESSING

(76) Inventors: Jie Su, Edison, NJ (US); Jiang Lu, Milpitas, CA (US); Hua Chung, San Jose, CA (US); Wei-Yung Hsu, San Jose, CA (US); David Bour, Cupertino, CA (US)

(21) Appl. No.: 13/485,671

(22) Filed: May 31, 2012

Related U.S. Application Data
(60) Provisional application No. 61/496,468, filed on Jun. 13, 2011.

(51) Int. Cl. H01L 21/20

(52) U.S. Cl. 438/478; 257/E21.09

(57) ABSTRACT

Enhanced magnesium incorporation into gallium nitride films through high pressure or ALD-type processing is described. In an example, a method of fabricating a group III-nitride film includes flowing a group III precursor, a nitrogen precursor, and a p-type dopant precursor into a reaction chamber having a substrate therein. A p-type doped group III-nitride layer is formed in the reaction chamber, above the substrate, while a total pressure in the reaction chamber is approximately in the range of 300-760 Torr.

### CROSS-REFERENCE TO RELATED APPLICATIONS

This application claims the benefit of U.S. Provisional Application No. 61/496,468, filed Jun. 13, 2011, the entire contents of which are hereby incorporated by reference herein.

### BACKGROUND

1) Field

Embodiments of the present invention pertain to the field of group III-nitride materials and, in particular, to enhanced magnesium incorporation into gallium nitride films through high pressure or ALD-type processing.

2) Description of Related Art

Group III-V materials are playing an ever increasing role in the semiconductor and related, e.g. light-emitting diode (LED), industries. Often, doped group III-V materials are difficult to grow or deposit without the formation of defects or low dopant incorporation. For example, high p-type dopant incorporation such as magnesium into select films, e.g. a gallium nitride film, is not straightforward in many applications.

### SUMMARY

Embodiments of the present invention include approaches for enhanced magnesium incorporation into gallium nitride films through high pressure or ALD-type processing.

In an embodiment, a method of fabricating a group III-nitride film includes flowing a group III precursor, a nitrogen precursor, and a p-type dopant precursor into a reaction chamber having a substrate therein. A p-type doped group III-nitride layer is formed in the reaction chamber, above the substrate, while a total pressure in the reaction chamber is approximately in the range of 300-760 Torr.

In an embodiment, a method of fabricating a group III-nitride film includes flowing a group III precursor, a nitrogen precursor, and a p-type dopant precursor to a reaction chamber having a substrate therein. A p-type doped group III-nitride layer is formed in the reaction chamber, above the substrate, by alternating group III precursor-rich and nitrogen precursor-rich pulses of the flowed group III precursor, nitrogen precursor, and p-type dopant precursor into the reaction chamber.

In an embodiment, a method of fabricating a group III-nitride film includes flowing a group III precursor, a nitrogen precursor, and a p-type dopant precursor to a reaction chamber having a substrate therein. A p-type doped group III-nitride layer is formed in the reaction chamber, above the substrate, by quasi alternating group III precursor-rich and nitrogen precursor-rich pulses of the flowed group III precursor, nitrogen precursor, and p-type dopant precursor into the reaction chamber. The group III precursor-rich pulses are performed at a first temperature. The nitrogen precursor-rich pulses performed at a second, different, temperature.

### BRIEF DESCRIPTION OF THE DRAWINGS

FIG. 1 is a plot of properties for structures including a magnesium doped gallium nitride (pGaN) layer fabricated at a baseline pressure of 100 Torr and at a high pressure of 500 Torr, in accordance with an embodiment of the present invention.

FIG. 2 is a plot of flow as a function of time for precursor gases used in an atomic layer epitaxy (ALE) formation of a magnesium doped gallium nitride layer, in accordance with an embodiment of the present invention.

FIG. 3 is a schematic cross-sectional view of an MOCVD chamber suitable for the fabrication of magnesium doped gallium nitride materials, in accordance with an embodiment of the present invention.

FIG. 4 illustrates a block diagram of an exemplary computer system, in accordance with an embodiment of the present invention.

FIG. 5 illustrates a system suitable for fabrication of magnesium doped gallium nitride materials, in accordance with an embodiment of the present invention.

FIG. 6 illustrates a cross-sectional view of a magnesium-doped gallium nitride (GaN)-based light-emitting diode (LED), in accordance with an embodiment of the present invention.

### DETAILED DESCRIPTION

Enhanced magnesium incorporation into gallium nitride films through high pressure or ALD-type processing is described. In the following description, numerous specific details are set forth, such as processing conditions and MOCVD chamber configurations, in order to provide a thorough understanding of embodiments of the present invention. It will be apparent to one skilled in the art that embodiments of the present invention may be practiced without these specific details. In other instances, well-known features, such as tool layouts or specific diode configurations, are not described in detail in order to not unnecessarily obscure embodiments of the present invention. Furthermore, it is to be understood that the various embodiments shown in the Figures are illustrative representations and are not necessarily drawn to scale. Additionally, other arrangements and configurations may not be explicitly disclosed in embodiments herein, but are still considered to be within the spirit and scope of the invention.

Dopant materials and the dopant concentration therein typically determine the conductivity type and the free carrier concentration of a semiconductor layer. Use of both conductivity types in one material may render p-n junction formation possible, which is a basic requirement for numerous electronic or optoelectronic devices, and group III-N based devices in particular. High doping levels may be crucial for proper device operation and performance. Doping level may determine turn-on and operating voltage, parameters of contacts, current injection efficiency, or current spreading, among other performance parameters.

Group II-elements predominantly occupy group III sites in a III-V material due to their valence electron configuration, providing a good approach to forming p-type group III-nitrides. Group IV-elements may occupy group III sites resulting in n-type group III-nitrides. However, group IV-elements may instead occupy anion sites (group V sites) to provide a p-type material. Group IV species are unique in their ability to substitute either cation or anion sites, resulting either in excess electrons (n-type) or a deficit of electrons (p-type), respectively. Accordingly, group II, and magnesium in particular, is often selected to consistently fabricate p-type group III-nitride material layers. However, effective doping levels may need to be as high as 10¹⁹-10²⁰ cm⁻³ Mg incorporation to provide a hole concentration of approximately 10¹⁸ cm⁻³.

In accordance with embodiments of the present invention, described herein are methods of enhanced magnesium incorporation into gallium nitride films, systems for enhanced magnesium incorporation into gallium nitride films, and machine-accessible storage media having instructions stored thereon which cause a data processing system to perform a method of enhanced magnesium incorporation into gallium nitride films.

Light-emitting diodes (LEDs) and related devices may be fabricated from layers of, e.g., p-type group films, especially p-type group III-nitride films. Some embodiments of the present invention relate to forming p-type (e.g., magnesium doped) gallium nitride (GaN) layers in a dedicated chamber of a fabrication tool, such as in a dedicated MOCVD chamber. In some embodiments of the present invention, p-type GaN is a binary GaN film, but in other embodiments, p-type GaN is a ternary film (e.g., p-type InGaN, p-type AlGaN) or is a quaternary film (e.g., p-type InAlGaN). In at least some embodiments, the p-type group III-nitride material layers are formed epitaxially. They may be formed directly on a substrate or on a buffer layer disposed on a substrate.

In an aspect of the present invention, methods for growth of magnesium doped gallium nitride (GaN) at high pressure are described. In an embodiment, a method for the growth of a high quality magnesium doped GaN layer at high pressure is used to achieve high hole concentration (cc), e.g., approximately 10¹⁸ cm⁻³, with high magnesium activation ratio (e.g., greater than approximately 3% hole contribution, with the remainder interstitial or self-compensated), and low resistivity (e.g., less than approximately 2 Ohm·cm). In one embodiment, the high pressure growth is performed approximately in the range of 300 Torr to 760 Torr, and possibly even higher). One or more of the carrier gas flow, type, chamber spacing between the showerhead and the wafer, or a combination thereof, may be adjusted accordingly to accommodate the high pressure growth conditions.

Due to the solubility of magnesium (Mg) in the solid phase and self-compensation by VN (nitrogen vacancy) or other donor type defects, the doping efficiency (or activation ratio) of Mg is typically in the range of 0.1-3%. However, the precise value may depend on the Mg dose level and growth conditions. P-type doped gallium nitride (p-GaN) may be a critical layer in an LED structure for providing the holes for recombination with electrons to convert the electrical energy to light emission. The optical performance of the LED (LOP) and electrical properties (Vf, Ir) may be significantly affected by the quality of p-GaN, for example, by the hole cc, mobility, and resistivity of the film.

In an embodiment, p-GaN is grown under relatively high growth pressure for the purpose of one or more of providing a relatively the higher Mg activation ratio, achieving a higher hole concentration, or achieving low bulk resistivity in a formed p-GaN layer or film. In one embodiment, the high growth pressure is performed at a total chamber pressure approximately in the range of 300 Torr to 760 Torr, or greater. In a specific such embodiment, the total chamber pressure is maintained at a pressure approximately in the range of 300-500 Torr. In one embodiment, a higher pressure may be desired, but the deposition process may be limited by existing hardware or by pre-reactions. As a comparison, a baseline or conventional pressure is typically approximately 100 Torr. The pressures described herein may be an essentially constant pressure and represent a total pressure such as a total chamber pressure. In an embodiment, by increasing pressure (e.g., to approximately 500 Torr as compared with the conventional 100 Torr), the growth rate of the p-GaN film is actually decreased. However, in one embodiment, the decreased growth rate is accompanied by increased Mg incorporation due to lower nitrogen vacancy formation, leading to less effective, and otherwise detrimental, counter doping.

In one embodiment, the higher total reaction pressure (e.g., chamber pressure) is accompanied by adjusting total flow to maintain the flow velocity of precursors into a reaction chamber and associated residence flow time at the elevated pressure. For example, in a specific such embodiment, a conventional total flow rate is 50 SLM (e.g., a rate used at 100 Torr), whereas a flowrate of approximately 100 SLM is used at an elevated pressure of approximately 500 Torr. In a particular embodiment, the flow rate is increased by increasing the flow rate of all incoming gases by an approximately equal factor, e.g., increasing the flows of Cp₂Mg, trimethyl gallium (TMGa), NH₃, and N₂/H₂ carrier, all by the same multiplier. In an alternative particular embodiment, the flow rate is increased by increasing only the flow rate of the carrier gas.

In one embodiment, the higher total reaction pressure (e.g., chamber pressure) is achieved by adjusting the spacing between the showerhead and the wafer surface in a reaction chamber. For example, in a specific such embodiment, a conventional spacing is approximately 10 millimeters (e.g., a spacing used at 100 Torr), whereas a spacing approximately in the range of 5-6 millimeters is used at an elevated pressure of approximately 500 Torr.

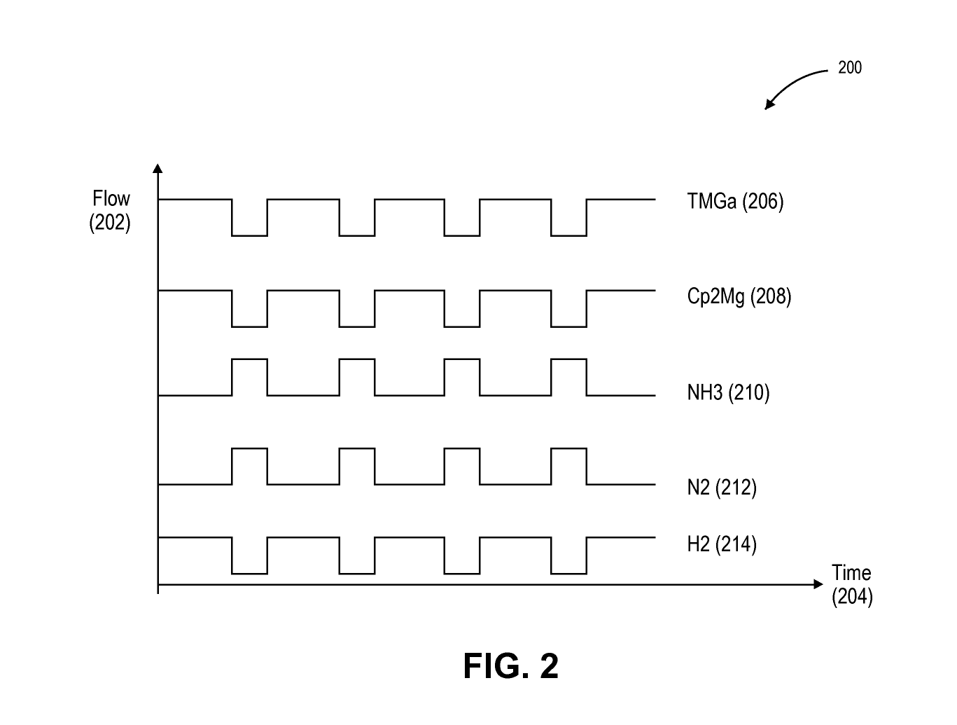

In one embodiment, the higher total reaction pressure (e.g., chamber pressure) is accompanied by adjusting the group V/group III precursor ratio and metal organic (MO) flow for better Mg incorporation and suppression of nitrogen vacancy formation. In a specific such embodiment, a relative amount of ammonia (NH₃) as a nitrogen source gas is decreased at increased pressure to avoid pre-reaction. Thus, perhaps counter-intuitively, the use of less ammonia actually decreases nitrogen vacancy formation at elevated pressures. In one embodiment, a carrier gas or a mixture with H₂, N₂, Ar, or other inert gas is modified to provide for an increase of Mg incorporation efficiency (e.g., in a particular embodiment, N₂ outperforms H₂ at a flowrate of 100 SLM). In one embodiment, a higher pressure is accompanied by use of alternative nitrogen precursors (alternative to conventional NH₃ flow), such as plasma, rf, or UV activated nitrogen for p-GaN for the purpose of reduction of N vacancy formation. In a particular such embodiment, the alternative nitrogen source is a nitrogen-based plasma, rf-activated nitrogen, UV-activated nitrogen, or hydrazine. In one embodiment, TMGa, Cp₂Mg, NH3, H₂ flows are alternated in groupings during the growth to enhance Mg incorporation and reduce nitrogen vacancy, as described in much greater detail below, in association with FIG. 2.

In an embodiment, the magnesium doped GaN film or layer has a high hole concentration greater than approximately 5E17 cm⁻³. In an embodiment, the magnesium doped GaN film or layer has a high magnesium activation efficiency greater than approximately 2%. In an embodiment, the magnesium doped GaN film or layer has a high mobility greater than approximately 10 (cm²/v-s) at hole concentration greater than 5E17 cm⁻³. In an embodiment, the magnesium doped GaN film or layer has a bulk resistivity of less than approximately 2 ohm·cm. In a combination embodiment, the magnesium doped GaN film or layer has a high hole concentration greater than approximately 5E17 cm⁻³, a high magnesium activation efficiency greater than approximately 2%, a high mobility greater than approximately 10 at hole concentration greater than 5E17 cm⁻³, and a bulk resistivity of less than approximately 2 ohm·cm.

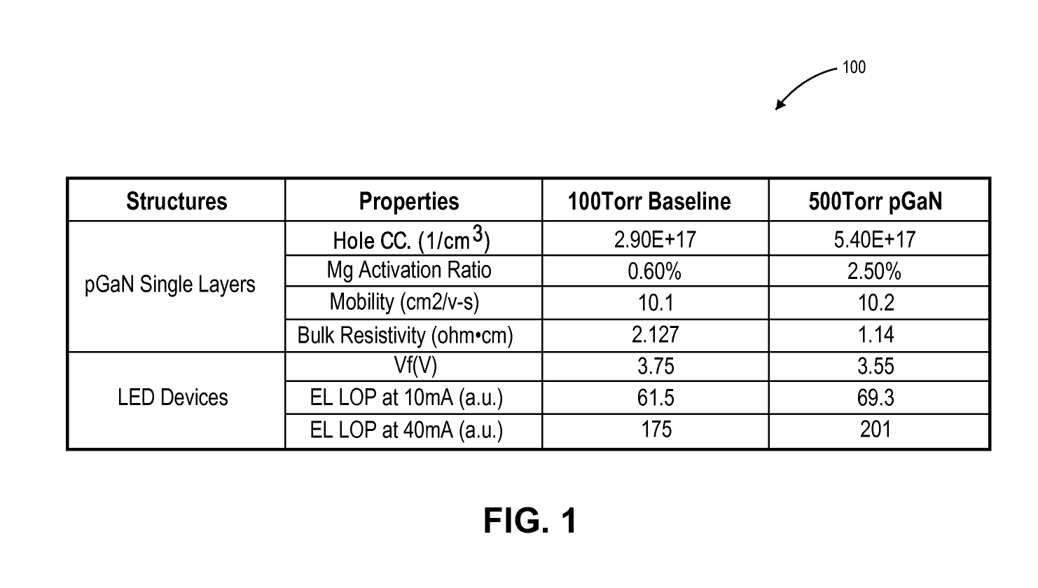

FIG. 1 is a plot 100 of properties for structures including a magnesium doped gallium nitride (pGaN) layer fabricated at a baseline pressure of 100 Torr and at a high pressure of 500 Torr, in accordance with an embodiment of the present invention. Referring to plot 100, for a single layer structure, the magnesium doped gallium nitride fabricated at the baseline pressure of 100 Torr has a lower hole concentration (hole CC. (1/cm³), a lower magnesium activation ratio, a lower mobility, and a higher bulk resistivity as compared with the magnesium doped gallium nitride fabricated at the high pressure of 500 Torr. Referring again to plot 100, for an LED device, an LED device including a magnesium doped gallium nitride layer fabricated at the baseline pressure of 100 Torr has a higher forward voltage (Vf) and a lower EL light output power (LOP) (at both 10 mA and 40 mA) as compared with an LED device including a magnesium doped gallium nitride layer fabricated at the high pressure of 500 Torr. Thus, in accordance with an embodiment of the present invention, a magnesium doped gallium nitride layer fabricated at 500 Torr shows better single layer film properties and LED device performance as compared with a magnesium doped gallium nitride layer fabricated at 100 Torr.

In another aspect of the present invention, atomic layer epitaxy (ALE) of magnesium doped gallium nitride is described. In an embodiment, the atomic layer epitaxy (ALE) of Mg doped GaN provides a high quality p-GaN layer or film. In one embodiment, a key is to promote a Ga-rich cycle to promote Mg incorporation and a N-rich condition to minimize nitrogen-vacancy.

There may be many issues related to Mg doped GaN grown by MOCVD, such as (1) limited solubility of Mg in GaN, resulting in a low Mg level as low 10²⁰ cm⁻³ range (attempts to increase Mg level exceeding this limit have typically only led to the formation of Mg₃N₂ precipitates and inverted domains of N-polarity), (2) hydrogen passivation by forming a Mg—H complex and self-compensation with nitrogen vacancy (VN) formation. These may be two competing mechanisms in that both passivate Mg in the as-grown GaN layer. However, H-passivation is preferred over VN compensation, since H—Mg bonds can be dissociated post-growth by a thermal annealing or other methods such as low energy electron beam radiation (LEEBI), activation with minority-carrier injection under bias, radiation by Excimer-laser or X-ray, and plasma-assisted activation (PAA) using oxygen and nitrogen. Other issues may include (3) low active ratio, only ˜1-2% may be activated due to the high acceptor activation energy ˜180 meV. For example, only 10¹⁷-10¹⁸ cm⁻³ hole concentration may be realized with Mg doping level up to the limit of 10²⁰ cm⁻³.

Based the above factors, in an embodiment, the best approach of growing p-GaN is to enhance Mg incorporation into the solid film without deteriorating the film quality, while minimizing the formation of VN. In one embodiment, it is possible through modulation epitaxy with alternating Ga-rich condition and N-rich conditions to effectively establish the periodic buildup and depletion process to facilitate the incorporation of Mg into Ga substitutional sites while suppressing the formation of VN, which is performed through alternating the N-rich and Ga-rich conditions.

In an embodiment, a method of epitaxy of Mg doped GaN by atomic layer epitaxy (ALE) is provided. In one such embodiment, a key is to create a Ga-rich condition by flowing only TMGa and CP₂Mg during the MO cycle, and flowing NH₃ or an activated N₂ precursor during the hydride cycle. Preferably, in a specific embodiment, hydrogen is used as carrier gas during the MO cycle and nitrogen is used as a carrier gas during the hydride cycle. By this approach, Mg may be more efficiently incorporated into Ga substitutional sites during the MO cycle, while nitrogen vacancies may be minimized during the hydride cycle under more N-rich conditions.

In another embodiment, atomic layer epitaxy is performed using a quasi type of alternating layer epitaxy (as compared with the above distinctly alternating approach). For example, in one embodiment, one or more monolayers are grown under the Ga-rich MO cycles, and one or more monolayers are grown under N-rich hydride cycles. In the distinctly alternating approach MO precursors and nitrogen precursors are alternated during the atomic layer epitaxy. In the quasi approach, both MO precursors and nitrogen precursors are presented during both cycles, but the cycles are modulated by the V/III ratio, pressure, total flow, or even temperature (described in greater detail below) etc. In an embodiment, the ALE growth is carried out by the traditional MOCVD system, or by a modified chamber suitable for the atomic layer epitaxy (e.g., in one such case, no showerhead with separated plenums is required).

In an embodiment of the quasi approach, pressure is modulated. For example, in one embodiment, 1:1 pressure cycles of approximately 500 Torr/approximately less than 50 Torr are repeated during the flow of p-GaN precursors. In a specific embodiment, the duration of each cycle is approximately in the range of 1-3 seconds (not including ramp rates of approximately 20 Torr/second and ramp times of approximately 20 seconds between the two pressures) with deposition gases flowed equally through both pressure cycles and ramping times. In another specific such embodiment, the duration of each cycle is approximately in the range of 1-3 seconds (not including ramp rates of approximately 20 Torr/second and ramp times of approximately 20 seconds between the two pressures) with deposition gases flowed equally through both pressure cycles but not flowed during ramping times.

General challenges for p-GaN by MOCVD may include limited solubility of Mg (e.g., a limit of low 10²⁰ cm⁻³ range). Attempts to increase Mg level with high Mg fluxes may result in Mg segregation or Mg₃N₂ precipitates at the surface, deterioration of crystal quality, and polarity inverted domain. High activation energy (e.g., approximately 180 meV), H passivation and self-compensation with nitrogen vacancy (V_{N}), and only low active ratio (˜1-2%) may be achieved by conventional MOCVD approach. Such high resistive p-GaN may hinder ohmic contact formation and cause current crowding for an LED fabricated there from. In an embodiment, a high performance p-GaN layer is achieved by using one or more approaches described herein. For example, in an embodiment, a p-GaN layer is fabricated with a higher activation efficiency (e.g., greater than approximately 2%, with a target approximately in the range of 3-5%), a high hole concentration (e.g., greater than approximately 10¹⁸ cm⁻³), a high mobility (e.g., greater than approximately 15-20), excellent crystal quality with minimized nitrogen vacancy and inverted polarity domains, and additional features such as, but not limited to, growth at lower temperatures, no additional post-growth annealing.

In an embodiment, modulation epitaxy is used as an approach to optimize growth conditions for high performance p-GaN. Unlike Mg δ-doping or interrupted growth approach, in one embodiment, the goal here is to improve Mg incorporation and H-passivation during Ga-rich condition and reduce nitrogen-vacancy formation during N-rich conditions by alternating between the Ga-rich and N-rich conditions.

In an embodiment, an ALE-Atomic layer epitaxy approach uses two cycles: an MO cycle and a hydride cycle. The MO cycle is used to promote Ga-rich conditions for enhanced Mg incorporation, while the hydride cycle is used to promote N-rich conditions to minimize nitrogen-vacancy. During the MO cycle, only Ga and Mg precursors, such as TMGa and Cp₂Mg, are used (but the approach is by no means limited to these two precursors). During the hydride cycle, only NH₃ or some other activated N₂ precursor is used. In one embodiment, the carrier gases H₂ and N₂ are alternated during the MO cycle and the hydride cycle. For example, H₂ may be used during the MO cycle, while N₂ is used during the hydride cycle. In a specific embodiment, growth of a p-GaN layer is performed by strictly one monolayer per cycle.

FIG. 2 is a plot 200 of flow 202 as a function of time 204 for precursor gases used in an atomic layer epitaxy (ALE) formation of a magnesium doped gallium nitride layer, in accordance with an embodiment of the present invention. Referring to plot 200, alternating pulses of NH₃ flow 210/N₂ flow 212 and trimethyl gallium (TMGa) flow 206/Cp₂Mg flow 208/H₂ flow 214 are repeated during formation of a magnesium doped gallium nitride layer.

As mentioned above, in an embodiment, a variation of ALE is alternating layer epitaxy. In one such embodiment, several monolayers are grown during the Ga-rich cycle and hydride cycle instead of strictly one monolayer per cycle. In one embodiment, both MO precursors and nitrogen precursors are present during the two cycles, while the modulation is performed through alternating one or more of V/III ratio, pressure, total flow, or temperature, etc. The growth may progress by the formation of one or more monolayers per cycle.

As an example, epitaxy of Mg doped GaN with rapid temperature modulation is performed. In an embodiment, rapid temperature modulation provides improved growth of Mg doped GaN with for higher activation ratio and higher mobility. In one such embodiment, growth temperature conditions (such as chamber temperature or chuck temperature) are alternated between a relatively high temperature and a relatively low temperature during the epitaxy of Mg—GaN. In one embodiment, this approaches leads to formation of a Ga-rich condition at lower temperature (e.g., approximately in the range of 800-900° C.) due to the reduced NH₃ decomposition efficiency, while N-rich conditions can be rendered at higher growth temperatures (e.g., approximately greater than 1000° C.).

The growth of p-GaN may not be ideal under either Ga-rich or N-rich conditions alone. Thus, in an embodiment, the two growth conditions are oscillated with abrupt transitions between them. With the capability of lamp-heated MOCVD system developed at Applied Materials, the temperature of the susceptor may be modulated with rapid ramping up and ramping down, e.g., up to 10° C./sec, or even 15-20° C./sec. For example, in one embodiment, the growth is oscillated between the lower temp TL and the higher temp TH, with ΔT approximately in the range of 100-200° C. In one embodiment, this approach facilitates a relatively increased Mg substitution into substitutional sites of Ga, minimizes the formation of VN, and prevents the polarity inversion. Other embodiments may include, but need not be limited to, modulation of the flow of NH₃ or Cp₂Mg together with the temperature modulation.

In another aspect of the present invention, regarding a nitrogen source, modified MOCVD deposition techniques, such as plasma-assisted MOCVD may produce relatively more reactive species at low growth temperatures as compared with conventional MOCVD processes. For example, in accordance with an embodiment of the present invention, plasma-assisted MOCVD is used to provide a greater concentration of reactive nitrogen at low growth temperatures as compared with conventional MOCVD processes. As an example, a low temperature approach for depositing magnesium (Mg)-doped p-GaN is performed with a high concentration of active nitrogen (N) made available by plasma-assisted MOCVD. Since the availability of active nitrogen is not as heavily tied to reaction temperature in this approach, in an embodiment, nitrogen-rich GaN is deposited at relatively low growth temperatures, e.g., in the range of 570-720 degrees Celsius.

Also described herein are plasma-assisted MOCVD conditions that do not yield a substantial amount of free hydrogen. For example, in an embodiment, an extremely low ammonia flow, e.g., 1 SLM versus 4-50 SLM in conventional MOCVD, is used in a plasma. The species generated include a variety of species or radicals, such as hydrazine (N₂H₄) or NH₂ and NH radicals, but very little relative hydrogen produced. In an embodiment, by generating reactive nitrogen without the added generation of substantial free hydrogen, otherwise inhibiting reactions are mitigated or eliminated.

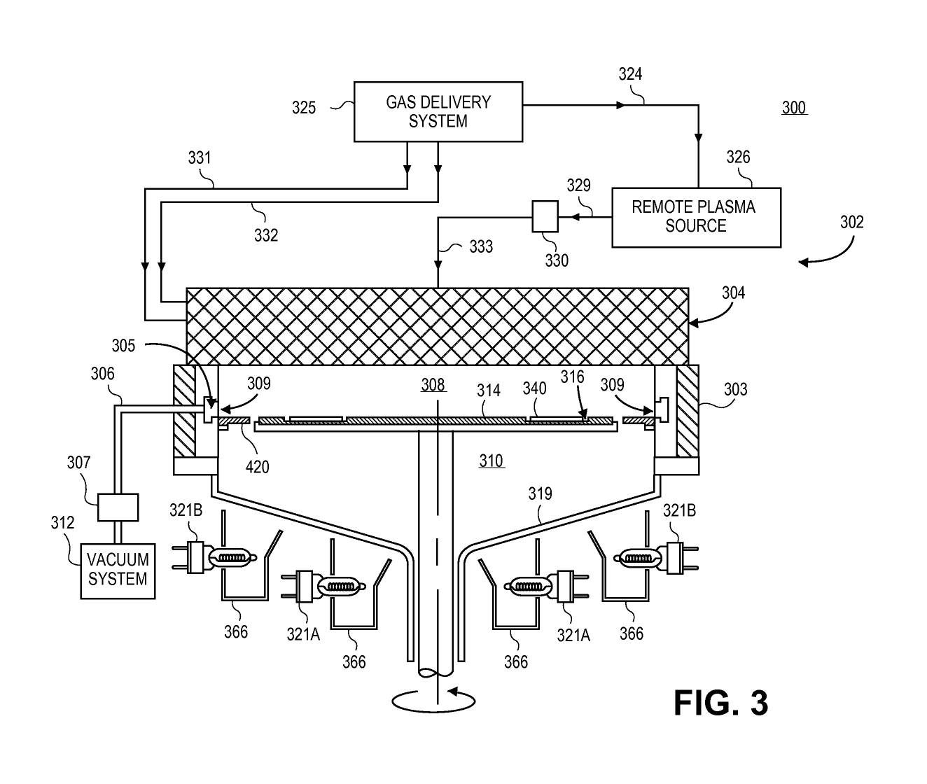

An example of an MOCVD deposition chamber which may be utilized for fabrication of p-type group III-nitride materials, e.g., magnesium doped gallium nitride, in accordance with embodiments of the present invention, is illustrated and described with respect to FIG. 3.

FIG. 3 is a schematic cross-sectional view of an MOCVD chamber according to an embodiment of the invention. The apparatus 300 shown in FIG. 3 includes a chamber 302, a gas delivery system 325, a remote plasma source 326, and a vacuum system 312. The chamber 302 includes a chamber body 303 that encloses a processing volume 308. A showerhead assembly 304 is disposed at one end of the processing volume 308, and a substrate carrier 314 is disposed at the other end of the processing volume 308. A lower dome 319 is disposed at one end of a lower volume 310, and the substrate carrier 314 is disposed at the other end of the lower volume 310. The substrate carrier 314 is shown in process position, but may be moved to a lower position where, for example, the substrates 340 may be loaded or unloaded. An exhaust ring 320 may be disposed around the periphery of the substrate carrier 314 to help prevent deposition from occurring in the lower volume 310 and also help direct exhaust gases from the chamber 302 to exhaust ports 309. The lower dome 319 may be composed of transparent material, such as high-purity quartz, to allow light to pass through for radiant heating of the substrates 340. The radiant heating may be provided by a plurality of inner lamps 321A and outer lamps 321B disposed below the lower dome 319, and reflectors 366 may be used to help control chamber 302 exposure to the radiant energy provided by inner and outer lamps 321A, 321B. Additional rings of lamps may also be used for finer temperature control of the substrate 340.

The substrate carrier 314 may include one or more recesses 316 within which one or more substrates 340 may be disposed during processing. The substrate carrier 314 may carry six or more substrates 340. In one embodiment, the substrate carrier 314 carries eight substrates 340. It is to be understood that more or less substrates 340 may be carried on the substrate carrier 314. Typical substrates 340 may include sapphire, silicon carbide (SiC), silicon, or gallium nitride (GaN). It is to be understood that other types of substrates 340, such as glass substrates 340, may be processed. Substrate 340 size may range from 50 mm-100 mm in diameter or larger. The substrate carrier 314 size may range from 200 mm-750 mm. The substrate carrier 314 may be formed from a variety of materials, including SiC or SiC-coated graphite. It is to be understood that substrates 340 of other sizes may be processed within the chamber 302 and according to the processes described herein. The showerhead assembly 304 may allow for more uniform deposition across a greater number of substrates 340 and/or larger substrates 340 than in traditional MOCVD chambers, thereby increasing throughput and reducing processing cost per substrate 340.

The substrate carrier 314 may rotate about an axis during processing. In one embodiment, the substrate carrier 314 may be rotated at about 2 RPM to about 100 RPM. In another embodiment, the substrate carrier 314 may be rotated at about 30 RPM. Rotating the substrate carrier 314 aids in providing uniform heating of the substrates 340 and uniform exposure of the processing gases to each substrate 340.

The plurality of inner and outer lamps 321A, 321B may be arranged in concentric circles or zones (not shown), and each lamp zone may be separately powered. In one embodiment, one or more temperature sensors, such as pyrometers (not shown), may be disposed within the showerhead assembly 304 to measure substrate 340 and substrate carrier 314 temperatures, and the temperature data may be sent to a controller (not shown) which can adjust power to separate lamp zones to maintain a predetermined temperature profile across the substrate carrier 314. In another embodiment, the power to separate lamp zones may be adjusted to compensate for precursor flow or precursor concentration non-uniformity. For example, if the precursor concentration is lower in a substrate carrier 314 region near an outer lamp zone, the power to the outer lamp zone may be adjusted to help compensate for the precursor depletion in this region.

The inner and outer lamps 321A, 321B may heat the substrates 340 to a temperature of about 400 degrees Celsius to about 1200 degrees Celsius. It is to be understood that the invention is not restricted to the use of arrays of inner and outer lamps 321A, 321B. Any suitable heating source may be utilized to ensure that the proper temperature is adequately applied to the chamber 302 and substrates 340 therein. For example, in another embodiment, the heating source may comprise resistive heating elements (not shown) which are in thermal contact with the substrate carrier 314.

A gas delivery system 325 may include multiple gas sources, or, depending on the process being run, some of the sources may be liquid sources rather than gases, in which case the gas delivery system may include a liquid injection system or other means (e.g., a bubbler) to vaporize the liquid. The vapor may then be mixed with a carrier gas prior to delivery to the chamber 302. Different gases, such as precursor gases, carrier gases, purge gases, cleaning/etching gases or others may be supplied from the gas delivery system 325 to separate supply lines 331, 332, and 333 to the showerhead assembly 304. The supply lines 331, 332, and 333 may include shut-off valves and mass flow controllers or other types of controllers to monitor and regulate or shut off the flow of gas in each line.

A conduit 329 may receive cleaning/etching gases from a remote plasma source 326. The remote plasma source 326 may receive gases from the gas delivery system 325 via supply line 324, and a valve 330 may be disposed between the showerhead assembly 304 and remote plasma source 326. The valve 330 may be opened to allow a cleaning and/or etching gas or plasma to flow into the showerhead assembly 304 via supply line 333 which may be adapted to function as a conduit for a plasma. In another embodiment, apparatus 300 may not include remote plasma source 326 and cleaning/etching gases may be delivered from gas delivery system 325 for non-plasma cleaning and/or etching using alternate supply line configurations to shower head assembly 304.

The remote plasma source 326 may be a radio frequency or microwave plasma source adapted for chamber 302 cleaning and/or substrate 340 etching. Cleaning and/or etching gas may be supplied to the remote plasma source 326 via supply line 324 to produce plasma species which may be sent via conduit 329 and supply line 333 for dispersion through showerhead assembly 304 into chamber 302. Gases for a cleaning application may include fluorine, chlorine or other reactive elements.

In another embodiment, the gas delivery system 325 and remote plasma source 326 may be suitably adapted so that precursor gases may be supplied to the remote plasma source 326 to produce plasma species which may be sent through showerhead assembly 304 to deposit CVD layers, such as group films, for example, on substrates 340. In general, a plasma, which is a state of matter, is created by the delivery of electrical energy or electromagnetic waves (e.g., radio frequency waves, microwaves) to a process gas (e.g., precursor gases) to cause it to at least partially breakdown to form plasma species, such as ions, electrons and neutral particles (e.g., radicals). In one example, a plasma is created in an internal region of the plasma source 326 by the delivery electromagnetic energy at frequencies less than about 100 gigahertz (GHz). In another example, the plasma source 326 is configured to deliver electromagnetic energy at a frequency between about 0.4 kilohertz (kHz) and about 200 megahertz (MHz), such as a frequency of about 162 megahertz (MHz), at a power level less than about 4 kilowatts (kW). It is believed that the formed plasma enhances the formation and activity of the precursor gas(es) so that the activated gases, which reach the surface of the substrate(s) during the deposition process can rapidly react to form a layer that has improved physical and electrical properties.

A purge gas (e.g., nitrogen) may be delivered into the chamber 302 from the showerhead assembly 304 and/or from inlet ports or tubes (not shown) disposed below the substrate carrier 314 and near the bottom of the chamber body 303. The purge gas enters the lower volume 310 of the chamber 302 and flows upwards past the substrate carrier 314 and exhaust ring 320 and into multiple exhaust ports 309 which are disposed around an annular exhaust channel 305. An exhaust conduit 306 connects the annular exhaust channel 305 to a vacuum system 312 which includes a vacuum pump (not shown). The chamber 302 pressure may be controlled using a valve system 307 which controls the rate at which the exhaust gases are drawn from the annular exhaust channel 305.

Embodiments of the present invention may be provided as a computer program product, or software, that may include a machine-readable medium having stored thereon instructions, which may be used to program a computer system (or other electronic devices) to perform a process according to embodiments of the present invention. In one embodiment, the computer system is coupled with apparatus 300 described in association with FIG. 3. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

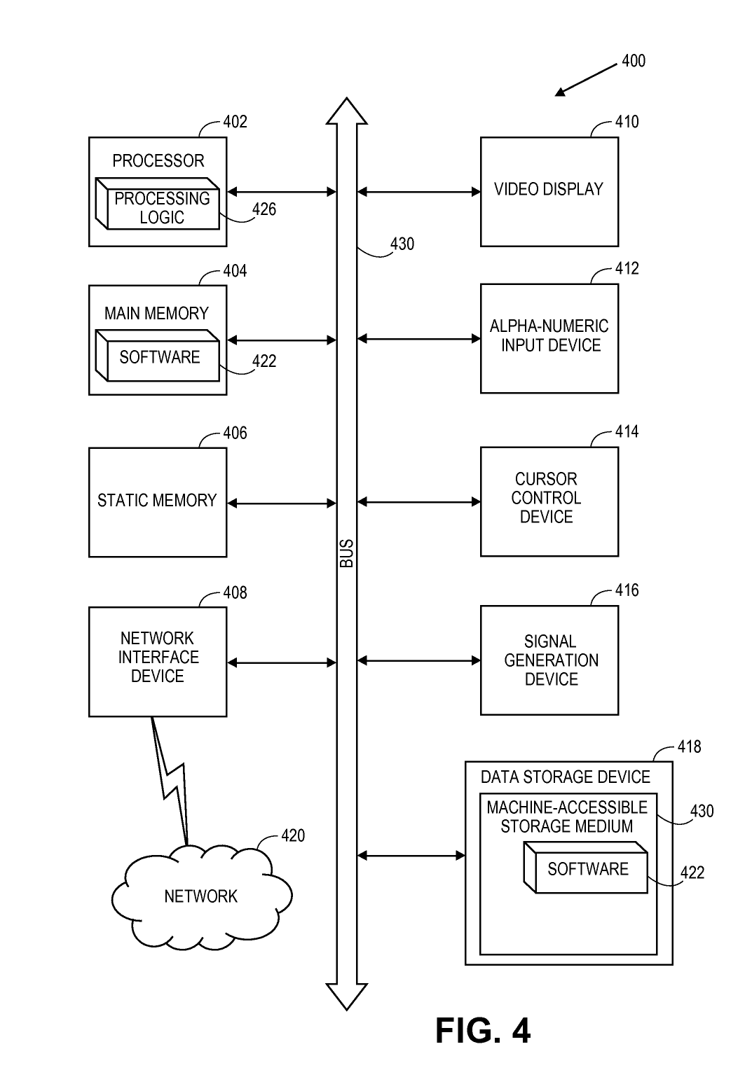

FIG. 4 illustrates a diagrammatic representation of a machine in the exemplary form of a computer system 400 within which a set of instructions, for causing the machine to perform any one or more of the methodologies described herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies described herein.

The exemplary computer system 400 includes a processor 402, a main memory 404 (e.g., read-only memory (ROM), flash memory, dynamic random access memory (DRAM) such as synchronous DRAM (SDRAM) or Rambus DRAM (RDRAM), etc.), a static memory 406 (e.g., flash memory, static random access memory (SRAM), etc.), and a secondary memory 418 (e.g., a data storage device), which communicate with each other via a bus 430.

Processor 402 represents one or more general-purpose processing devices such as a microprocessor, central processing unit, or the like. More particularly, the processor 402 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 402 may also be one or more special-purpose processing devices such as an application specific integrated circuit (ASIC), a field programmable gate array (FPGA), a digital signal processor (DSP), network processor, or the like. Processor 402 is configured to execute the processing logic 426 for performing the operations described herein.

The computer system 400 may further include a network interface device 408. The computer system 400 also may include a video display unit 410 (e.g., a liquid crystal display (LCD), a light emitting diode display (LED), or a cathode ray tube (CRT)), an alphanumeric input device 412 (e.g., a keyboard), a cursor control device 414 (e.g., a mouse), and a signal generation device 416 (e.g., a speaker).

The secondary memory 418 may include a machine-accessible storage medium (or more specifically a computer-readable storage medium) 431 on which is stored one or more sets of instructions (e.g., software 422) embodying any one or more of the methodologies or functions described herein. The software 422 may also reside, completely or at least partially, within the main memory 404 and/or within the processor 402 during execution thereof by the computer system 400, the main memory 404 and the processor 402 also constituting machine-readable storage media. The software 422 may further be transmitted or received over a network 420 via the network interface device 408.

While the machine-accessible storage medium 431 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies of the present invention. The term “machine-readable storage medium” shall accordingly be taken to include, but not be limited to, solid-state memories, and optical and magnetic media.

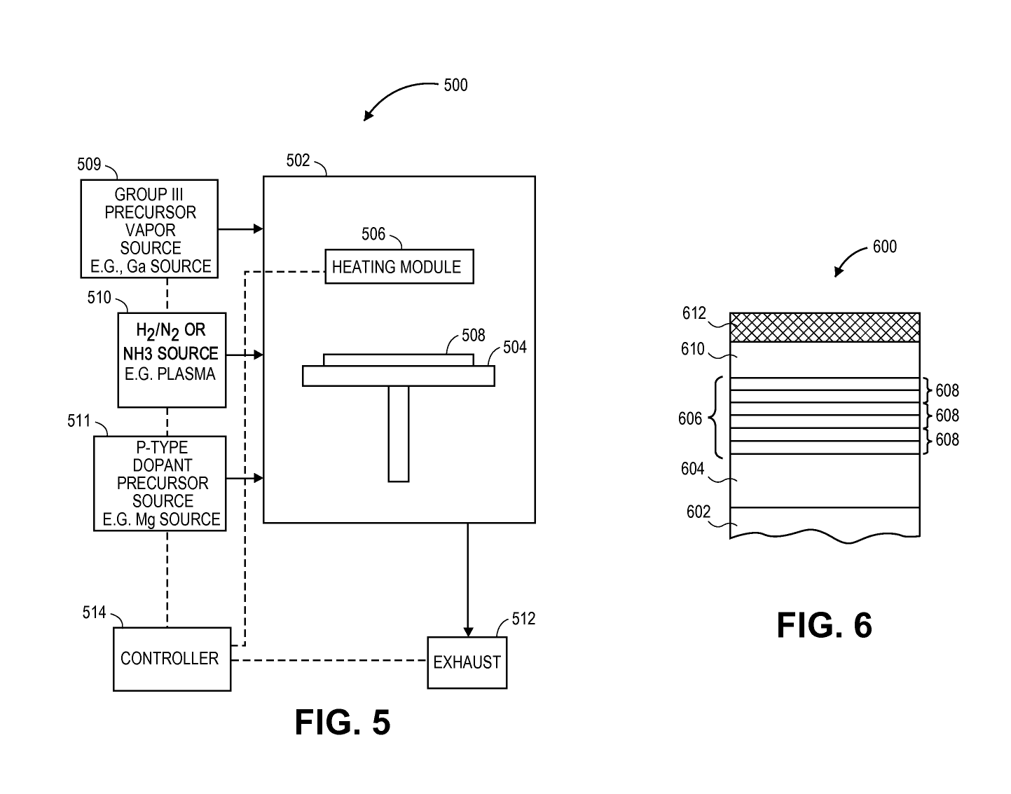

FIG. 5 illustrates a system suitable for fabrication of p-type group III-nitride materials, e.g. magnesium doped gallium nitride, in accordance with an embodiment of the present invention.

Referring to FIG. 5, the system 500 may include a deposition chamber 502 that includes a substrate support 504 and a heating module 506. The substrate support 504 may be adapted to support a substrate 508 during film formation within the chamber 502, and the heating module 506 may be adapted to heat the substrate 508 during film formation within the deposition chamber 502. More than one heating module, and/or other heating module locations may be used. The heating module 506 may include, for example, a lamp array or any other suitable heating source and/or element.

The system 500 may also include a group III, e.g., gallium, vapor source 509, a N₂/H₂ or NH₃ source such as a plasma source 510, a p-type dopant, e.g. magnesium, precursor source 511 (e.g., Cp₂Mg), and an exhaust system 512 coupled to the deposition chamber 502. The system 500 may also include a controller 514 coupled to the deposition chamber 502, the group III vapor source 509, the N₂/H₂ or NH₃ source 510, the p-type dopant precursor source 511, and/or the exhaust system 512. The exhaust system 512 may include any suitable system for exhausting waste gasses, reaction products, or the like from the chamber 502, and may include one or more vacuum pumps. The N₂/H₂ or NH₃ source 510 may, in accordance with an embodiment of the present invention, be suitable to provide a substantial amount of nitrogen-containing species for reaction with vapor for the group III vapor source 509 and with p-type dopant precursors from the p-type dopant precursor source 511. The N₂/H₂ or NH₃ source 510 may be used to generate a plasma in the deposition chamber or remotely and introduced into the deposition chamber.

The controller 514 may include one or more microprocessors and/or microcontrollers, dedicated hardware, a combination the same, etc., that may be employed to control operation of the deposition chamber 502, the group III vapor source 509, the N₂/H₂ or NH₃ source 510, the p-type dopant precursor source 511, and/or the exhaust system 512. In at least one embodiment, the controller 514 may be adapted to employ computer program code for controlling operation of the system 500. For example, the controller 514 may perform or otherwise initiate one or more of the operations of any of the methods/processes described herein, including the method described in association with Flowchart 200. Any computer program code that performs and/or initiates such operations may be embodied as a computer program product. Each computer program product described herein may be carried by a medium readable by a computer (e.g., a floppy disc, a compact disc, a DVD, a hard drive, a random access memory, etc.).

Group III precursor vapor may be created by placing an elemental group III species into a vessel, such as a crucible, and heating the vessel to melt the elemental group III species. The vessel may be heated to a temperature of from about 100 degrees Celsius to about 250 degrees Celsius. In some embodiments, nitrogen gas may be passed over the vessel containing the molten elemental group III species at a pressure of about 1 Torr and pumped to the process chamber. The nitrogen may be flowed at a rate of about 200 standard cubic centimeters per minute (sccm). The group III precursor vapor may be drawn into the process chamber by a vacuum. In an alternative embodiment, the substrate may be exposed to the group III precursor vapor, the N₂/H₂ or NH₃ source and one or more of hydrogen and hydrogen chloride. The hydrogen and/or the hydrogen chloride may increase the rate of deposition. In another embodiment of the present invention, a group III-nitride film may be deposited on a substrate using a group III sesquichloride precursor and/or a group III hydride precursor.

A magnesium doped gallium nitride layer fabricated in a MOCVD chamber may be used in the fabrication of a light-emitting diode device. For example, FIG. 6 illustrates a cross-sectional view of a gallium nitride (GaN)-based light-emitting diode (LED), in accordance with an embodiment of the present invention.

Referring to FIG. 6, a GaN-based LED 600 includes an n-type GaN template 604 (e.g., n-type GaN, n-type InGaN, n-type AlGaN, n-type InAlGaN) on a substrate 602 (e.g., planar sapphire substrate, patterned sapphire substrate (PSS), silicon substrate, silicon carbide substrate). The GaN-based LED 600 also includes a multiple quantum well (MQW), or active region, structure or film stack 606 on or above the n-type GaN template 604 (e.g., an MQW composed of one or a plurality of field pairs of InGaN well/GaN barrier material layers 608, as depicted in FIG. 6). The GaN-based LED 600 also includes a p-type GaN (p-GaN) layer or film stack 610 on or above the MQW 606, and a metal contact or ITO layer 612 on the p-GaN layer.

In an embodiment, the p-type GaN is a magnesium doped GaN film or layer. In one such embodiment, the magnesium doped GaN film or layer has a high hole concentration greater than approximately 5E17 cm⁻³. In one such embodiment, the magnesium doped GaN film or layer has a high magnesium activation efficiency greater than approximately 2%. In one such embodiment, the magnesium doped GaN film or layer has a high mobility greater than approximately 10 at hole concentration greater than 5E17 cm⁻³. In one such embodiment, the magnesium doped GaN film or layer has a bulk resistivity of less than approximately 2 ohm·cm. In a combination embodiment, the magnesium doped GaN film or layer has a high hole concentration greater than approximately 5E17 cm⁻³, a high magnesium activation efficiency greater than approximately 2%, a high mobility greater than approximately 10 at hole concentration greater than 5E17 cm⁻³, and a bulk resistivity of less than approximately 2 ohm·cm.

It is to be understood that embodiments of the present invention are not limited to formation of layers on patterned sapphire substrates. Other embodiments may include the use of any suitable patterned single crystalline substrate upon which a group III-nitride epitaxial film may be formed. The patterned substrate may be formed from a substrate, such as but not limited to a sapphire (Al₂O₃) substrate, a silicon carbide (SiC) substrate, a silicon on diamond (SOD) substrate, a quartz (SiO₂) substrate, a glass substrate, a zinc oxide (ZnO) substrate, a magnesium oxide (MgO) substrate, and a lithium aluminum oxide (LiAlO₂) substrate. Any well know method, such as masking and etching may be utilized to form features, such as posts, from a planar substrate to create a patterned substrate. In a specific embodiment, however, the patterned substrate is a (0001) patterned sapphire substrate (PSS). Patterned sapphire substrates may be ideal for use in the manufacturing of LEDs because they increase the light extraction efficiency which is extremely useful in the fabrication of a new generation of solid state lighting devices. Other embodiments include the use of planar (non-patterned) substrates, such as a planar sapphire substrate. In other embodiments, the approaches herein are used to provide a group III-material layer directly on a silicon substrate.

In some embodiments, growth of a p-type gallium nitride or related film on a substrate is performed along a (0001) Ga-polarity, N-polarity, or non-polar a-plane {112-0} or m-plane {101-0}, or semi-polar planes. In some embodiments, posts formed in a patterned growth substrate are round, triangular, hexagonal, rhombus shape, or other shapes effective for block-style growth. In an embodiment, the patterned substrate contains a plurality of features (e.g., posts) having a cone shape. In a particular embodiment, the feature has a conical portion and a base portion. In an embodiment of the present invention, the feature has a tip portion with a sharp point to prevent over growth. In an embodiment, the tip has an angle (θ) of less than 145° and ideally less than 110°. Additionally, in an embodiment, the feature has a base portion which forms a substantially 90° angle with respect to the xy plane of the substrate. In an embodiment of the present invention, the feature has a height greater than one micron and ideally greater than 1.5 microns. In an embodiment, the feature has a diameter of approximately 3.0 microns. In an embodiment, the feature has a diameter height ratio of approximately less than 3 and ideally less than 2. In an embodiment, the features (e.g., posts) within a discrete block of features (e.g., within a block of posts) are spaced apart by a spacing of less than 1 micron and typically between 0.7 to 0.8 microns.

It is also to be understood that embodiments of the present invention need not be limited to p-GaN as a group III-V layer in an LED device, such as described in association with FIG. 6. For example, other embodiments may include any p-type group III-nitride epitaxial film that can be suitably deposited by MOCVD, or the like. The p-type group III-nitride film may be a binary, ternary, or quaternary compound semiconductor film formed from a group III element or elements selected from gallium, indium and aluminum and nitrogen. That is, the p-type group III-nitride crystalline film can be any solid solution or alloy of one or more Group III element and nitrogen, such as but not limited to p-type GaN, AlN, InN, AlGaN, InGaN, InAlN, and InGaAlN.

However, in a specific embodiment, the group III-nitride film is a p-type gallium nitride (GaN) film. In a particular embodiment, the p-type dopant is magnesium. The p-type group III-nitride film can have a thickness between 2-500 microns and is typically formed between 2-15 microns. In an embodiment of the present invention, the p-type group III-nitride film has a thickness of at least 3.0 microns to sufficiently suppress threading dislocations. The p-type group III-nitride film can be p-typed doped using any p-type dopant such as but not limited Mg, Be, Ca, Sr, or any Group I or Group II element have two valence electrons. The group III-nitride film can be p-type doped to a conductivity level of between 1×10¹⁶ to 1×10²⁰ atoms/cm³.

It is to be understood that on the above processes may be performed in a dedicated chamber within a cluster tool, or other tool with more than one chamber, e.g. an in-line tool arranged to have a dedicated chamber for fabricating layers of an LED. It is also to be understood that embodiments of the present invention need not be limited to the fabrication of LEDs. For example, in another embodiment, devices other than LED devices may be fabricated by an MOCVD process using a nitrogen-based plasma and a p-type dopant source, such as but not limited to field-effect transistor (FET) devices.

Thus, approaches for enhanced magnesium incorporation into gallium nitride films through high pressure or ALD-type processing has been disclosed.

What is claimed is:

1. A method of fabricating a group III-nitride film, the method comprising:
flowing a group III precursor, a nitrogen precursor, and a p-type dopant precursor into a reaction chamber having a substrate therein;
forming, in the reaction chamber, a p-type doped group III-nitride layer above the substrate while a total pressure in the reaction chamber is approximately in the range of 300-760 Torr.

2. The method of claim 1, wherein flowing the group III precursor and the p-type dopant precursor comprises flowing a gallium precursor and a magnesium precursor, respectively.

3. The method of claim 2, wherein flowing the gallium precursor, the nitrogen precursor, and the magnesium precursor comprises flowing trimethyl gallium (TMGa), ammonia (NH₃), and dicyclopentadienyl magnesium (Cp₂Mg), respectively.

4. The method of claim 1, wherein the total pressure in the reaction chamber is substantially determined by cumulative partial pressures of the group III precursor, the nitrogen precursor, the p-type dopant precursor, and a carrier gas.

5. The method of claim 1, wherein forming the p-type doped group III-nitride layer comprises forming the layer having a hole concentration of approximately 10¹⁸ cm⁻³, a magnesium activation ratio greater than approximately 3% hole contribution, and a resistivity less than approximately 2 ohm·cm).

6. The method of claim 1, wherein flowing the group III precursor, the nitrogen precursor, and the p-type dopant precursor into the reaction chamber comprises flowing the precursors through a showerhead disposed above the substrate, the spacing between the showerhead and the substrate approximately in the range of 5-6 millimeters.

7. The method of claim 1, wherein forming the p-type doped group III-nitride layer comprises using a total pressure in the reaction chamber of approximately 500 Torr.

8. A method of fabricating a group III-nitride film, the method comprising:
flowing a group III precursor, a nitrogen precursor, and a p-type dopant precursor to a reaction chamber having a substrate therein;
forming, in the reaction chamber, a p-type doped group III-nitride layer above the substrate by alternating group III precursor-rich and nitrogen precursor-rich pulses of the flowed group III precursor, nitrogen precursor, and p-type dopant precursor into the reaction chamber.

9. The method of claim 8, wherein flowing the group III precursor and the p-type dopant precursor comprises flowing a gallium precursor and a magnesium precursor, respectively.

10. The method of claim 9, wherein flowing the gallium precursor, the nitrogen precursor, and the magnesium precursor comprises flowing trimethyl gallium (TMGa), ammonia (NH₃) or activated nitrogen (N₂), and dicyclopentadienyl magnesium (Cp₂Mg), respectively.

11. The method of claim 10, wherein the group III precursor-rich pulses comprise flowing TMGa and CP₂Mg, but not NH₃ or activated N₂, into the reaction chamber.

12. The method of claim 10, wherein the nitrogen precursor-rich pulses comprise flowing only NH₃ or activated N₂, but not TMGa or CP₂Mg, into the reaction chamber.

13. The method of claim 10, wherein the group III precursor-rich pulses comprise flowing TMGa and CP₂Mg and hydrogen carrier gas, but not NH₃ or activated N₂, into the reaction chamber, and wherein the nitrogen precursor-rich pulses comprise flowing only NH₃ or activated N₂ and nitrogen carrier gas, but not TMGa or CP₂Mg, into the reaction chamber.

14. The method of claim 8, wherein forming the p-type doped group III-nitride layer comprises forming the layer having a hole concentration of approximately 10¹⁸ cm⁻³, a magnesium activation ratio greater than approximately 3% hole contribution, and a resistivity less than approximately 2 ohm·cm).

15. A method of fabricating a group III-nitride film, the method comprising:
flowing a group III precursor, a nitrogen precursor, and a p-type dopant precursor to a reaction chamber having a substrate therein;
forming, in the reaction chamber, a p-type doped group III-nitride layer above the substrate by quasi alternating group III precursor-rich and nitrogen precursor-rich pulses of the flowed group III precursor, nitrogen precursor, and p-type dopant precursor into the reaction chamber, the group III precursor-rich pulses performed at a first temperature and the nitrogen precursor-rich pulses performed at a second, different, temperature.

16. The method of claim 15, wherein the group III precursor-rich pulses are performed at a temperature approximately in the range of 800-900° C., and the nitrogen precursor-rich pulses are performed at a temperature approximately greater than 1000° C.

17. The method of claim 15, wherein flowing the group III precursor and the p-type dopant precursor comprises flowing a gallium precursor and a magnesium precursor, respectively.

18. The method of claim 17, wherein flowing the gallium precursor, the nitrogen precursor, and the magnesium precursor comprises flowing trimethyl gallium (TMGa), ammonia (NH₃) or activated nitrogen (N₂), and dicyclopentadienyl magnesium (Cp₂Mg), respectively.

19. The method of claim 18, wherein both the group III precursor-rich pulses and the nitrogen precursor-rich pulses comprise flowing TMGa, CP₂Mg, and NH₃ or activated N₂ into the reaction chamber.

20. The method of claim 15, wherein forming the p-type doped group III-nitride layer comprises forming the layer having a hole concentration of approximately 10¹⁸ cm⁻³, a magnesium activation ratio greater than approximately 3% hole contribution, and a resistivity less than approximately 2 ohm·cm).
